(19) United States
(12) Patent Application Publication
(10) Pub. No.: US 2019/0259587 A1
(43) Pub. Date: Aug. 22, 2019

(54) DEPOSITION PREVENTIVE PLATE, SPUTTERING APPARATUS, AND MANUFACTURING METHOD FOR ELECTRONIC COMPONENT

(71) Applicant: Toshiba Memory Corporation, Minato-ku (JP)

(72) Inventor: Tatsuhiko MIURA, Yokkaichi (JP)

(73) Assignee: Toshiba Memory Corporation, Minato-ku (JP)

(21) Appl. No.: 16/027,563

(22) Filed: Jul. 5, 2018

(30) Foreign Application Priority Data
Feb. 22, 2018 (JP) 2018-029701

(51) Int. Cl. H01J 37/34; H01J 37/32

(52) U.S. Cl. CPC H01J 37/3426; H01J 37/3438; H01J 37/32477

(57) ABSTRACT

A deposition preventive plate according to an embodiment is a deposition preventive plate arranged on an outer periphery of a cathode electrode capable of holding a target material inside a sputtering apparatus, and the deposition preventive plate includes a base material and sprayed deposit arranged over the base material and containing Si.

### CROSS-REFERENCE TO RELATED APPLICATIONS

This application is based upon and claims the benefit of priority from Japanese Patent Application No.2018-029701, filed on Feb. 22, 2018; the entire content of which are incorporated herein by reference.

### FIELD

Embodiments of the present invention described herein relate generally to a deposition preventive plate, a sputtering apparatus, and a manufacturing method for an electronic component.

### BACKGROUND

In a sputtering apparatus, sputtered particles from a target material are made to adhere to a substrate inside the apparatus, and a film is deposited on the substrate. Inside the sputtering apparatus, a deposition preventive plate is attached to an outer periphery of the target material. It is desirable that deposition characteristics be stable from the beginning of attaching the deposition preventive plate.

### BRIEF DESCRIPTION OF THE DRAWINGS

FIG. 1 is a diagram illustrating an entire structure of a sputtering apparatus according to an embodiment;

FIG. 2 provides cross-sectional views of a deposition preventive plate according to the embodiment; and

FIG. 3 is a flowchart illustrating exemplary procedures of sputtering film forming processing in the sputtering apparatus to which the deposition preventive plate according to the embodiment is attached.

### DETAILED DESCRIPTION

A deposition preventive plate according to an embodiment is a deposition preventive plate arranged on an outer periphery of a cathode electrode capable of holding a target material inside a sputtering apparatus, and the deposition preventive plate includes: a base material; and a sprayed deposit arranged over the base material and containing Si.

An exemplary embodiment of the present invention will be explained below in detail with reference to the accompanying drawings. Note that the present invention is not limited to the following embodiment. Additionally, constituent elements in the following embodiment include those that can be easily assumed by a man skilled in the art or those that are substantially the same.

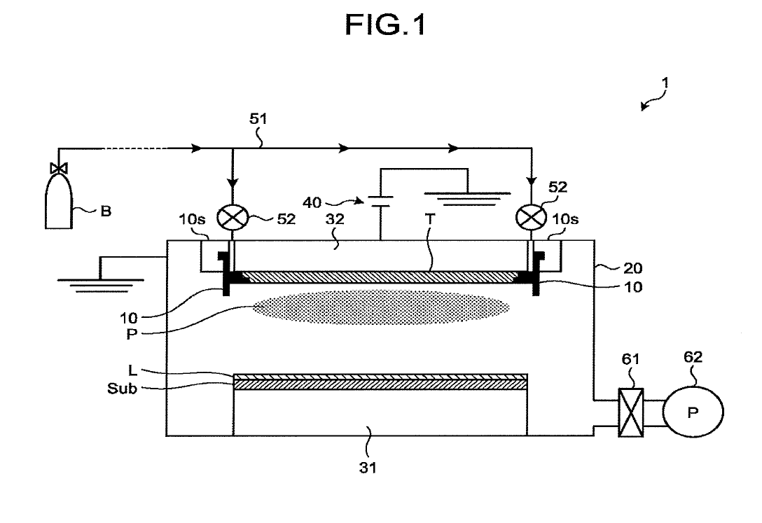

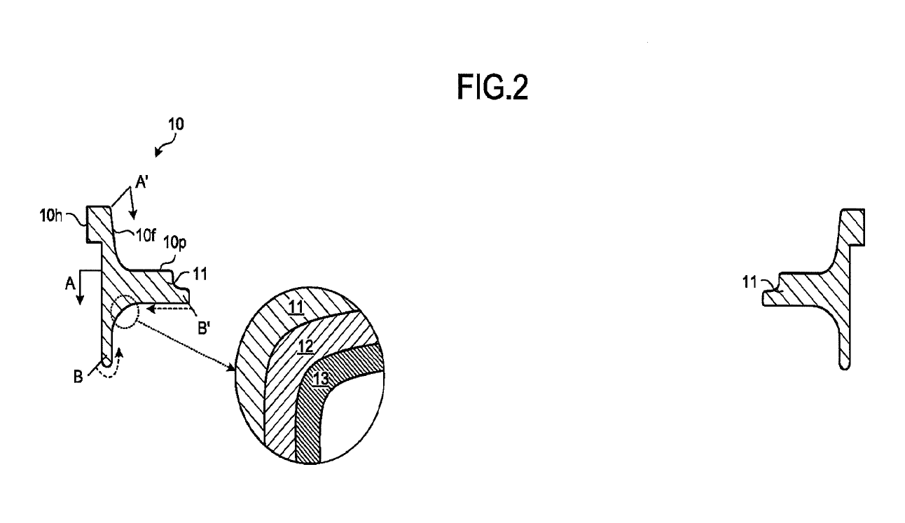

A deposition preventive plate, a sputtering apparatus, and a manufacturing method for an electronic component according to an embodiment will be described with reference to FIGS. 1 and 2.

[Exemplary Structure of Sputtering Apparatus]

FIG. 1 is a diagram illustrating an entire structure of a sputtering apparatus 1 according to an embodiment. As illustrated in FIG. 1, the sputtering apparatus 1 includes: a processing vessel 20, a cathode electrode 32 arranged inside the processing vessel 20 and capable of holding a target material T; an anode electrode 31 arranged inside the processing vessel 20 and capable of holding a wafer Sub serving as a substrate onto which sputtered particles from the target material T made to adhere; and a deposition preventive plate 10 arranged on an outer periphery of the cathode electrode 32.

The processing vessel 20 contains a space to become a plasma space. The anode electrode 31 on which the wafer Sub can be placed is arranged at a lower portion of the processing vessel 20. The cathode electrode 32 is arranged at an upper portion of the processing vessel 20 in a manner facing the anode electrode 31. The cathode electrode 32 is, for example, a magnet electrode incorporating a permanent magnet that generates a magnetic field. Note that vertical arrangement of the anode electrode 31 and the cathode electrode 32 is relative, and the anode electrode 31 may be arranged at the upper portion of the processing vessel 20, and the cathode electrode 32 may be arranged at the lower portion of the processing vessel 20. Thus, the sputtering apparatus 1 is provided as a parallel plate type plasma apparatus, for example.

The cathode electrode 32 is capable of holding a target material T containing, for example, WSi₂ as a main component. The target material T has a disk-like shape, for example, and is held by the cathode electrode 32 while having a main face thereof facing the anode electrode 31 located below.

A deposition preventive plate support member 10s is arranged around the cathode electrode 32 so as to surround the cathode electrode 32. The annular deposition preventive plate 10 is attached to the deposition preventive plate support member 10s. With this structure, the deposition preventive plate 10 is arranged on the outer periphery of the target material I held by the cathode electrode 32.

The cathode electrode 32 is connected to a high voltage power source 40. The high voltage power source 40 can apply high voltage to the cathode electrode 32. Note that portions other than the cathode electrode 32 of the processing vessel 20, in other words, an upper surface, a side surface, and a lower surface are grounded. With this structure, the anode electrode 31 is grounded via the lower surface of the processing vessel 20. The deposition preventive plate 10 is grounded via the deposition preventive plate support member 10s and the upper surface of the processing vessel 20.

A gas supply pipe 51 is connected to the processing vessel 20. The gas supply pipe 51 has an upstream end connected to a bottle B, and a downstream end connected to the upper surface of the processing vessel 20, for example. The gas supply pipe 51 is provided with a valve 52. Supply of a gas into the processing vessel 20 can be started and stopped by opening and closing the valve 52. The gas supplied from the bottle B is introduced into the vicinity of a main surface of the target material T surrounded by the deposition preventive plate 10 from the upper surface of the processing vessel 20 through a gap between the target material T and the deposition preventive plate 10. The gas supplied into the processing vessel 20 is, for example, an Ar gas or the like.

The processing vessel 20 is connected to a pump 62 via a gate valve 61. For example, the gate valve 61 and the pump 62 are arranged at positions obliquely below the anode electrode 31 on which the wafer Sub is placed. Exhaust of the atmosphere inside the processing vessel 20 by the pump 62 can be started or stopped by opening and closing the gate valve 61.

With the above-described structure, the sputtering apparatus 1 generates plasma P inside the processing vessel 20, sputters the target material T, and deposits a sputtering film L such as a silicide (WSi₂) film by making sputtered particles adhere onto the wafer Sub.

Specifically, the pump 62 is actuated while opening the gate valve 61, and the atmosphere inside the processing vessel 20 is exhausted. Additionally, the valve 52 is opened to supply the gas from the bottle B into the processing vessel 20. Furthermore, high voltage is applied to the cathode electrode 32 by the high voltage power source 40. Consequently, plasma P is generated in the space inside the processing vessel 20. Then, cations (for example, Ar⁺ ions) inside the plasma P collide with the target material T held by the cathode electrode 32. The sputtered particles containing, for example, W and Si pop out from the target material T. The sputtered particles adhere to the wafer Sub held by the anode electrode 31, and the sputtering film L such as a WSi₂ film is deposited.

[Exemplary Structure of Deposition Preventive Plate]

Next, an exemplary structure of the deposition preventive plate 10 will be described with reference to FIG. 2.

FIG. 2 provides cross-sectional views of the deposition preventive plate 10 according to the embodiment. As illustrated in FIG. 2 (enlarged view inside a circle in FIG. 2), the deposition preventive plate 10 includes a base material 11 and a coating film 13 arranged over the base material 11. The coating film 13 is formed as a sprayed deposit containing Si. Additionally, the coating film 13 contains W that is a type of metal same as silicide contained in the target material T, and has a content rate of Si in atomic concentration higher than that of the silicide contained in the target material T. Such a deposition preventive plate 10 preferably includes a base film 12 between the base material 11 and the coating film 13.

Specifically, the deposition preventive plate 10 includes: a deposition preventive portion 10p having a substantially L-shaped cross section; a leg portion 10f extending from a bent portion of the deposition preventive portion 10p to the outside of the bent portion of the deposition preventive portion 10p; and a hook portion 10h provided at a distal end portion of the leg portion 10f.

When the deposition preventive plate 10 is attached to the inside the sputtering apparatus 1, a bent distal end portion of the substantially L-shaped deposition preventive portion 10p protrudes into a space of the processing vessel 20 from the main surface of the target material T in a manner surrounding the target material T. The sputtered particles having popped out from the target material T also scatter in directions other than the wafer Sub side, for example, in a side surface direction of the processing vessel 20. The protruding deposition preventive portion 10p of the deposition preventive plate 10 inhibits sputtered particles from scattering inside the processing vessel 20 by making at least part of the sputtered particles to adhere to the deposition preventive portion 10p.

The base material 11 has a shape almost similar to that of the deposition preventive plate 10, and is made of SUS, for example. The base film 1 is formed on a surface of the base material 11 from a point A to a point A′ in FIG. 2. The coating film 13 is formed on a surface of the base film 12 from at least a point B to a point B′ in FIG. 2. The base material 11 is exposed at the hook portion 10h, and therefore, the deposition preventive plate 10 can be electrically connected to the deposition preventive plate support member 10s and grounded when the deposition preventive plate 10 is attached to the sputtering apparatus 1.

The base film 12 is provided on the surface of the base material 11. The base film 12 is, for example, a plasma sprayed deposit containing Al as a main component. Al contained in the base film 12 has a weight concentration (weight percentage) of 99.9% or more, for example. The base film 12 has a resistance value of 0.5Ω or less.

The base film 12 has a film thickness of, preferably, 100 μm or more and 600 μm or less, for example, 300 μm. Since the base film 12 has the film thickness of 100 μm or more, it is possible to ease stress of the coating film 13 and prevent the coating film 13 from being peeled off at the time of forming the coating film 13 on the base film 12. Additionally, since the base film 12 has the film thickness of 100 μm or more, reproduction processing of the deposition preventive plate 10 is facilitated after operation for a predetermined time. In the reproduction processing of the deposition preventive plate 10, the base film 12 is dissolved in solvent or the like to peel off, together with the base film 12, the coating film 13 to which the sputtered particles are adhering, and after that, the base film 12 and the coating film 13 are newly formed. Additionally, since the base film 12 has the film thickness of 600 μm or less, it is possible to suppress the base film 12 from being broken by own stress of the base film 12 or the like.

The base film 12 is applied with, for example, rough surface processing, and the base film 12 has a surface roughness (Pa) of, for example, about several tens μm. Preferably, the base film 12 has the surface roughness of 10 μm or more from the viewpoint of controlling the surface roughness of the coating film 13.

The coating film 13 is provided on the base material 11 via the base film 12. The coating film 13 is, for example, a plasma sprayed deposit containing W and Si. The coating film 13 has the content rate of Si in atomic concentration (atomic percentage) higher than the content rate of Si in the target material T, and the content rate is preferably 66.7 atm % or more, more preferably 75.0 atm % or more, and still more preferably 99.6 atm % or more. Such a Si-rich coating film 13 can be obtained by adding Si during application of plasma spray treatment to the coating film 13 while using, as a base, the WSi₂ plasma sprayed deposit, for example. A part or all of W and Si inside the coating film 13 may be formed as silicide or may not be formed as silicide.

The coating film 13 has a resistance value larger than that of the base film 12 which has the resistance value of 0.5Ω or less, and the resistance value of 100Ω or more is preferable. The value depends on the content rate of Si inside the coating film 13, and the higher the content rate of Si is, the higher the resistance value is. Thus, the resistance value of the coating film 13 can be adjusted by the content rate of Si.

The coating film 13 has a film thickness of, preferably, 50 μm or more and 100 μm or less. Since the coating film 13 has the film thickness of 50 μm or more, the deposition preventive plate 10 can obtain a sufficient lifetime. Additionally, since the coating film 13 has the film thickness of 100 μm or less, it is possible to suppress the coating film 13 from being broken by own stress of the coating film 13 or the like.

The coating film 13 has a surface roughness (Ra) of, preferably, 10 μm or more, for example, about 30 μm. Since the coating film 15 is formed as a sprayed deposit, it is possible to obtain a surface rougher than that of a film formed by sputtering or chemical vapor deposition, for example. Furthermore, the surface roughness of the coating film 13 mainly depends on the surface roughness of the base film 12 that is the base. Additionally, the more the content rate of Si inside the coating film 13 is increased, the more the surface roughness of the coating film 13 also tends to be slightly increased. Since the coating film 13 has the surface roughness of 10 μm or more, it is possible to suppress sputtered particles having adhered to the surface from being peeled off and becoming a particle source.

Effects of the deposition preventive plate 10 having the above-described structure will be described.

First, in a case where a deposition preventive plate having only an Al plasma sprayed deposit is attached to the sputtering apparatus and a WSi₂ film is deposited as a reference example, a specific resistance value of the WSi₂ film result in being lower than a predetermined value at the beginning of attaching the deposition preventive plate, and in-plane uniformity of specific resistance values within a wafer also results in being inferior to the predetermined value (the specific resistance value of a wafer edge is low). In this case, seasoning the deposition preventive plate 10 under plasma for a predetermined time is required in order to make the specific resistance value of the WSi₂ film and the uniformity within a predetermined range.

The inventor of the present invention has made examination on an adhering matter on the surface of the deposition preventive plate 10 in the reference example after elapse of a predetermined time, and it is found that: the adhering matter is a mixture of W and Si and has a higher content rate of Si inside the adhering matter than that in silicide contained in a target material; and the surface of the adhering matter has high resistance value. Judging from this, it can be presumed that: the deposition preventive plate having a surface resistance value of 0.5Ω or less is in a state more surely grounded; and plasma inside the processing vessel tends to spread toward the deposition preventive plate. Additionally, it can be presumed that plasma is confined at a center of the processing vessel due to influence of a weakened a grounding level (grounding) of the deposition preventive plate as the surface resistance value of the deposition preventive plate is increased by the adhering matters. With this phenomenon, it can be considered that: in-plane thermal uniformity within the wafer is improved; and the characteristics of the WSi₂ film are improved.

Accordingly, the inventor of the present invention comes to find, as a result of the earnest research, that: it is possible to adjust, regardless of elapse of time, the resistance value on the surface of the deposition preventive plate 10 within a desired range by attaching, to the sputtering apparatus 1, the deposition preventive plate 10 that preliminarily has the coating film 13 sprayed with plasma. Additionally, it is also found that a WSi₂ film having a specific resistance value and uniformity within the predetermined value can be deposited from the beginning of attaching the deposition preventive plate 10 even without performing long-time seasoning.

Thus, since the deposition preventive plate 10 of the embodiment is attached to the sputtering apparatus 1, it is possible to obtain stable deposition characteristics from the beginning of attaching the deposition preventive plate 10. Consequently, a time required for seasoning can be reduced, and an operation rate of the sputtering apparatus 1 can be improved. Furthermore, wasteful consumption of the target material T by seasoning can be suppressed.

[Exemplary Manufacturing Processing for Electronic Component]

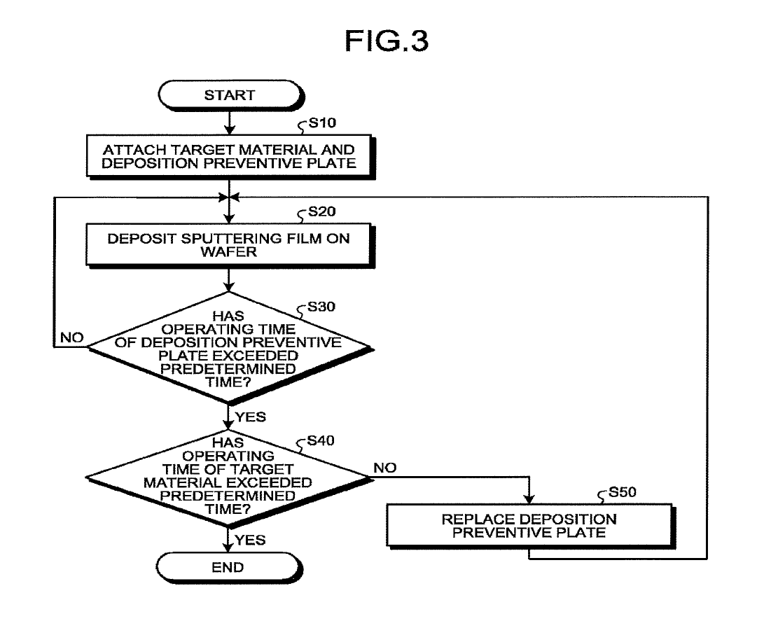

Next, as exemplary manufacturing processing for an electronic component, forming processing for a sputtering film L on the wafer Sub in the sputtering apparatus 1 to which the deposition preventive plate 10 according to an embodiment is attached will be described with reference to FIG. 3. FIG. 3 is a flowchart illustrating exemplary procedures in the forming processing for the sputtering film L in the sputtering apparatus 1 to which the deposition preventive plate 10 according to the embodiment is attached.

Specifically, the forming processing for the sputtering film L according to the embodiment is manufacturing processing for an electronic component in which the sputtering film L that is a silicide film is formed on a wafer Sub that is a semiconductor material, and the processing includes: attaching the target material T to the cathode electrode 32 arranged inside the processing vessel 20 of the sputtering apparatus 1; attaching, to the outer periphery of the cathode electrode 32, the deposition preventive plate 10 having the base material 11 and the coating film 13 arranged over the base material 11 and containing Si; and making sputtered particles scatter from the target material T by applying high voltage to the cathode electrode 32. Then, the sputtering film L is formed by making the scattering sputtered particles adhere onto the wafer Sub held by the anode electrode 31 arranged inside the processing vessel 20.

In other words, as illustrated in FIG. 3, for example, the target material T containing WSi₂ as a main component and the deposition preventive plate 10 are attached to the sputtering apparatus 1 in step S10. As for the target material T, a new one is attached. As for the deposition preventive plate 10, a new one or a recycled one is attached. In either case, the deposition preventive plate 10 is provided with the coating film 13 containing Si from the beginning of attachment.

In step S20, the sputtering film L is deposited on the wafer Sub. Specifically, plasma P such as an Ar gas is generated inside the processing vessel 20 of the sputtering apparatus 1, and the target material T is sputtered. The sputtered particles pop out from the target material T and adhere to the wafer Sub held by the anode electrode 31. When sputtering is continued for a predetermined time, the sputtering film L having a predetermined film thickness is deposited on the wafer Sub. Since the deposition preventive plate 10 including the coating film 13 is provided, the sputtering film L having a desired specific resistance value and desired in-plane uniformity is formed on the wafer Sub from the beginning of attaching the deposition preventive plate 10.

In step S30, it is determined whether an operating time of the deposition preventive plate 10 has exceeded a predetermined time. The determination may also be made by an operator or a maintenance manager of the sputtering apparatus 1. Alternatively, the sputtering apparatus 1 may have a function to issue an alarm when the operating time exceeds the predetermined time by providing a plasma time accumulator or the like in the sputtering apparatus 1.

In a case where the operating time has not yet exceeded the predetermined time (No), deposition processing in step S20 is repeated on the predetermined number of wafers Sub.

In a case where the operating time has exceeded the predetermined time (Yes), it is determined in step S40 whether the operating time of the target material T has exceeded a predetermined time. This determination is also performed by an operator or a function of the sputtering apparatus 1.

In a case where the operating time of the target material T has not yet exceeded the predetermined time (No), the deposition preventive plate 10 is replaced with a new one or a recycled one in step S50, and the deposition processing in step S20 is repeated. At this point also, the deposition preventive plate 10 includes the coating film 13 containing Si from the beginning of attachment. Since the deposition preventive plate 10 including the coating film 13 is provided, the sputtering film L having a desired specific resistance value and desired in-plane uniformity is formed on the wafer Sub from the beginning of attaching the deposition preventive plate 10.

In a case where the operating time of the target material T has exceeded the predetermined time (Yes), the deposition processing in the sputtering apparatus 1 is terminated.

### MODIFIED EXAMPLES

It is specified above that the base material 11 of the deposition preventive plate 10 is, for example, SUS, but a material other than SUS may also be used. The base material may also be a member of ceramic, quarts, Al, or the like, for example.

It is specified above that the base film 12 is, for example, a plasma sprayed deposit, but other sprayed deposits such as an arc sprayed deposit, a flame sprayed deposit, and the like may also be applied. Additionally, it is specified above that the base film 12 is, for example, Al, but a member other than Al may also be applied. The base film may also be a member of Ti, Ni, Ti/Ni hybrid material, or the like, for example. The base film formed of any one of these members may also be a plasma sprayed deposit.

Additionally, in a case where the film thickness of the coating film 13 is made sufficiently thin, the base film 12 may be unnecessary. In the case where the coating film 13 is thin, the coating film 13 has little stress, and it is possible to sufficiently suppress the coating film 13 from being broken by own stress even without the base film 12 that eases the stress.

It is specified above that the coating film 13 is a plasma sprayed deposit, but the coating film may also be another sprayed deposit such as an arc sprayed deposit, a flame sprayed deposit, and the like. Additionally, it is specified above that the coating film 13 contains W and Si, but another metal may be contained instead of W. For example, Mo and Si may be contained in the coating film. However, the metal inside the coating film is preferably a type of metal same as a metal contained in the target material. Consequently, metal contamination in the deposited sputtering film can be suppressed. Compositions, a resistance value, a film thickness, a surface roughness, and the like of the coating film including another metal like Mo can be similar to those of the coating film 13 of the embodiment. The coating film containing another metal may be a plasma sprayed deposit.

The coating film contains Si as a main component and may not contain any other metal. Si contained in the coating film has a weight concentration (weight percentage) of, for example, 99.9% or more and 100%. The coating film has a resistance value of, preferably, 760Ω or more, for example, about 1000Ω. Besides, the film thickness, surface roughness, and the like of the coating film can be similar to those of the coating film 13 of the embodiment. The coating film containing Si as a main component may be a plasma sprayed deposit or another sprayed deposit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A deposition preventive plate arranged on an outer periphery of a cathode electrode capable of holding a target material inside a sputtering apparatus, the deposition preventive plate comprising:
a base material; and
a sprayed deposit arranged over the base material and containing Si.

2. The deposition preventive plate according to claim 1, further comprising a film having a resistance value smaller than a resistance value of the sprayed deposit between the base material and the sprayed deposit.

3. The deposition preventive plate according to claim 1, wherein the sprayed deposit contains Si having an atomic concentration of 66.7 atm % or more.

4. The deposition preventive plate according to claim 1, wherein the sprayed deposit has a surface roughness of 10 μm or more.

5. The deposition preventive plate according to claim 1, wherein the sprayed deposit has a resistance value of 100Ω or more.

6. The deposition preventive plate according to claim 2, wherein
the film having the resistance value smaller than the resistance value of the sprayed deposit has a film thickness of 100 μm or more and 600 μm or less, and
the sprayed deposit has a film thickness of 50 μm or more and 100 μm or less.

7. A sputtering apparatus comprising:
a processing vessel;
a cathode electrode arranged inside the processing vessel and capable of holding a target material;
an anode electrode arranged inside the processing vessel and capable of holding a substrate onto which sputtered particles from the target material are made to adhere;
a power source connected to the cathode electrode and applying voltage to the cathode electrode; and
a deposition preventive plate that includes a base material and a sprayed deposit arranged over the base material and containing Si, and is arranged on an outer periphery of the cathode electrode.

8. The sputtering apparatus according to claim 7, wherein the deposition preventive plate further includes a film having a resistance value smaller than a resistance value of the sprayed deposit between the base material and the sprayed deposit.

9. The sputtering apparatus according to claim 7, wherein the sprayed deposit of the deposition preventive plate contains Si having an atomic concentration of 66.7 atm % or more.

10. The sputtering apparatus according to claim 7, wherein the sprayed deposit of the deposition preventive plate has a surface roughness of 10 μm or more.

11. The sputtering apparatus according to claim 7, wherein the sprayed deposit of the deposition preventive plate has a resistance value of 100Ω or more.

12. The sputtering apparatus according to claim 8, wherein
the film having the resistance value smaller than the resistance value of the sprayed deposit has a film thickness of 100 μm or more and 600 μm or less, and the sprayed deposit has a thickness of 50 μm or more and 100 μm or less.

13. A manufacturing method for an electronic component in which a silicide film is formed on a substrate, the method comprising:
attaching a target material to a cathode electrode arranged inside a processing vessel of a sputtering apparatus;
attaching, to an outer periphery of the cathode electrode, a deposition preventive plate including a base material and a coating film that is arranged over the base material and contains Si;
making sputtered particles scatter from the target material by applying voltage to the cathode electrode; and
forming the silicide film by making the scattering sputtered particles adhere onto the substrate held by an anode electrode arranged inside the processing vessel.

14. The manufacturing method for an electronic component according to claim 13, wherein the deposition preventive plate further includes a film having a resistance value smaller than a resistance value of the coating film between the base material and the coating film.

15. The manufacturing method for an electronic component according to claim 13, wherein
the target material contains silicide, and
the coating film of the deposition preventive plate contains a metal that is a type of metal same as the silicide contained in the target material, and contains the Si having a content rate in atomic concentration higher than a content rate of the silicide contained in the target material.

16. The manufacturing method for an electronic component according to claim 15, wherein the coating film contains the Si having an atomic concentration of 66.7 atm % or more.

17. The manufacturing method for an electronic component according to claim 13, wherein the coating film of the deposition preventive plate is a sprayed deposit.

18. The manufacturing method for an electronic component according to claim 13, wherein the coating film of the deposition preventive plate has a surface roughness of 10 μm or more.

19. The manufacturing method for an electronic component according to claim 13, wherein the coating film of the deposition preventive plate has a resistance value of 100Ω or more.

20. The manufacturing method for an electronic component according to claim 14, wherein
the film having the resistance value smaller than the resistance value of the coating film has a film thickness of 100 μm or more and 600 μm or less, and
the coating film has a film thickness of 50 μm or more and 100 μm or less.
